(19) United States
(12) Patent Application Publication
(10) Pub. No.: US 2009/0243668 A1
(43) Pub. Date: Oct. 1, 2009

(54) FREQUENCY DIVIDER SPEED BOOSTER

(75) Inventors: Guangbin Zhang, Sunnyvale, CA (US); Wei Deng, Sunnyvale, CA (US); Yu Shen Yang, San Jose, CA (US)

Correspondence Address: BLAKELY SOKOLOFF TAYLOR & ZAFMAN LLP, 1279 Oakmead Parkway, Sunnyvale, CA, 94085-4040, US

(73) Assignee: OMNIVISION TECHNOLOGIES, INC., Sunnyvale, CA (US)

(21) Appl. No.: 12/058,590

(22) Filed: Mar. 28, 2008

(51) Int. Cl. H03B 19/00

(52) U.S. Cl. 327/117; 327/115

(57) ABSTRACT

Embodiments of the present invention synthesize a core frequency divider by adding a switching feedback shell and using multiple clock edges to trigger the frequency divider. Feedback logic is used to determine which edge will be used. Embodiments allow multiple recursive use, which boosts the overall speed resulting frequency divider circuit 2^{N} times faster than the core frequency divider.

### BACKGROUND

1. Field

The present disclosure relates to frequency dividers, and more particularly, to digital frequency dividers.

2. Discussion of Related Art

Frequency dividers are important building blocks in phase lock loops (PLL). Phase-locked loops generally contain a phase detector (also referred to as a phase comparator), an amplifier, and a voltage-controlled oscillator (VCO). The phase detector is a device that compares two input frequencies, generating an output that is a measure of their phase difference. Phase-locked loops may be converted into frequency synthesizers by adding a frequency divider between the VCO and the phase detector. The frequency divider receives a high frequency input signal and outputs a lower frequency signal.

Traditionally, frequency dividers are synthesized using a digital counter and one or more logic gates. Synthesis can be accomplished using a hardware description language (HDL) such as Very High Speed Integrated Circuit Hardware Description Language (VHDL) or Verilog. The digital counter may be used to truncate a sequence and produce a divide-by-n output.

Current methods of synthesizing frequency dividers have limitations, however. For example, if the frequency divider is synthesized using a hardware description language, the frequency divider may be a traditional delay flip-flop (DFF)-based frequency divider. In this case, the output of one counter stage of an asynchronous digital counter is directly connected to the input of the next counter stage of the same asynchronous digital counter. The speed of the traditional DFF-based frequency divider is thus limited by the speed of the DFF and/or gate delay of the related logic circuits. If the divider ratio is large, a relatively complex digital logic circuit may be needed. These complex digital logic circuits normally have several stages of gates and each stage has a physical limitation of speed and/or propagation delay, depending on the semiconductor process.

Another limitation of current methods of synthesizing frequency dividers is that the resulting frequency dividers cannot divide by odd numbers. That is, they may only be able to divide by even numbers. For example, one common method of dividing a high frequency input is to divide the input by two and then to feed the half-frequency into a low-speed frequency divider. In some cases, it may be necessary to divide the input frequency multiple times to lower the speed, because the operating speed of the frequency divider is lower than the half-frequency of the input frequency. Even if the input frequency may have to be divided multiple times to be compatible with the operating frequency of the frequency divider, traditional methods are still limited to dividing by even numbers such as 2n, 4n, etc., where n is an integer.

### BRIEF DESCRIPTION OF THE DRAWINGS

In the drawings, like reference numbers generally indicate identical, functionally similar, and/or structurally equivalent elements. The drawing in which an element first appears is indicated by the leftmost digit(s) in the reference number, in which:

FIG. 1 is a high level block diagram of a frequency divider having a speed booster according to an embodiment of the present invention;

FIG. 2 is a block diagram of a frequency divider showing a speed booster in more detail according to an embodiment of the present invention;

FIG. 3 is a high level block diagram of a multilevel frequency divider having a speed booster according to an alternative embodiment of the present invention; and

FIG. 4 is a high level block diagram of a multilevel frequency divider having speed booster according to still another embodiment of the invention.

### DETAILED DESCRIPTION

In the below description, numerous specific details, such as, for example, particular processes, materials, devices, and so forth, are presented to provide a thorough understanding of embodiments of the invention. One skilled in the relevant art will recognize, however, that the embodiments of the present invention may be practiced without one or more of the specific details, or with other methods, components, etc. In other instances, structures or operations are not shown or described in detail to avoid obscuring the understanding of this description.

Reference throughout this specification to “one embodiment” or “an embodiment” means that a particular feature, structure, process, block, or characteristic described in connection with an embodiment is included in at least one embodiment of the present invention. Thus, the appearance of the phrases “in one embodiment” or “in an embodiment” in various places throughout this specification does not necessarily mean that the phrases all refer to the same embodiment. The particular features, structures, or characteristics may be combined in any suitable manner in one or more embodiments.

Embodiments of the present invention include a frequency divider circuit having a speed booster shell added to a core frequency divider. In some embodiments, the frequency divider circuit may receive an input clock and a control signal, and switch between a positive clock edge and a negative clock edge to be coupled to the core frequency divider. The control signal may be used to determine whether the positive clock edge or a negative clock edge is coupled to the core frequency divider. Depending on whether the positive clock edge or the negative clock edge is coupled to the core frequency divider, the frequency divider circuit may divide by even and odd numbers. As such, a frequency divider circuit implemented according to embodiments of the present invention may be more flexible than conventional frequency dividers.

For other embodiments, the divider circuit may receive input clocks whose frequencies are greater than the operating frequency of the core frequency divider. In one embodiment, if one speed booster shell is coupled to the core frequency divider, the input clock frequency to the divider circuit may be twice the core frequency. In an alternative embodiment, if two speed booster shells are included in the frequency divider circuit, the input clock frequency to the divider circuit may be four times the core frequency. Alternatively still, if three speed booster shells are included in the frequency divider circuit, the input clock frequency to the divider circuit may be eight times the core frequency. In this light, a frequency divider circuit implemented according to embodiments of the present invention may be faster than conventional frequency dividers. Other features and advantages of the present invention will be apparent from the accompanying drawings and from the detailed description that follows.

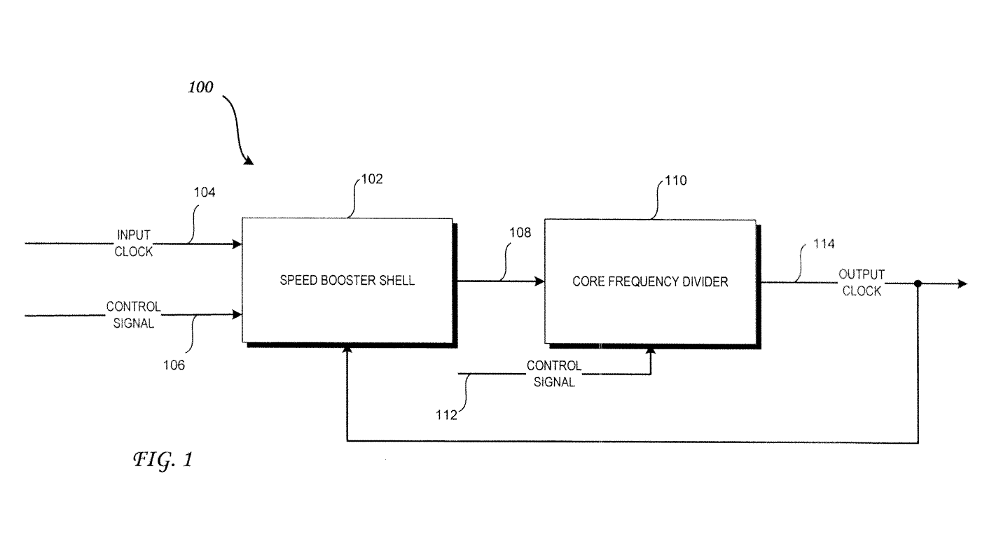

FIG. 1 illustrates a frequency divider circuit 100 according to one embodiment of the present invention. In the illustrated embodiment, a speed booster shell 102 includes a first input coupled to receive an input clock 104 and a second input coupled to receive a control signal 106. The speed booster shell 102 generates an output signal 108, which is coupled to an input of a core frequency divider 110. The frequency divider 110 has a second input coupled to receive a control signal 112. The frequency divider 110 generates an output clock 114, which is fed back to a third input of the speed booster shell 102.

The speed booster shell 102 may receive the input clock 104 and the control signal 106, and generate two or more clock edges. One clock edge may be a positive clock edge and the other clock edge may be a negative clock edge. The speed booster shell 102 may select at least one clock edge from the two or more clock edges and may apply the selected clock edge to the frequency divider 110 as the output signal 108. The control signal 106 may be used to determine whether the positive clock edge or the negative clock edge is applied to the input of the frequency divider 110. The control signal 106 also may be used to determine whether the frequency divider 110 is dividing by an odd integer or an even integer. In one embodiment, if the control signal 106 is a first logic value, the negative clock edge is selected and the frequency divider 110 is dividing by an even integer. In an alternative embodiment, if the control signal 106 is a second logic value, the positive clock edge is selected and the frequency divider 110 is dividing by an odd integer. In one embodiment, the first logic value is a logic zero and the second logic value is a logic one.

The frequency divider 110 may use the control signal 112 to generate the output clock 114 from the output signal 108. The control signal 112 may be used as a multiplier to determine by what integer to divide the applied output signal 108. For some embodiments, the control signal 106 may be concatenated with the control signal 112 such that the positive clock edge and the negative clock and the frequency divider 110 dynamically divides by both odd integers and even integers. In one embodiment, if the control signal 106 is zero, the positive clock edge is selected and the frequency divider 110 is dividing by an even integer. In an alternative embodiment, if the control signal 106 is one, the negative clock edge is selected and the frequency divider 110 is dividing by an odd integer. For example, the control signal 106 may be a div<0> vector, the control signal 112 may be a div<n: 1> vector, and concatenated, these two vectors are applied to a div<(n−1):0> input of the frequency divider 110.

In the illustrated embodiment, the output clock 114 is fed back to the speed booster shell 102. The frequency of the output clock 108 may depend on the feedback from the output clock 114. The speed booster shell 102 also may use the output clock 114 to determine which clock edge is selected.

For purposes of explanation, as an example assume that the frequency divider 110 can divide an input frequency F by one up to 2⁽ⁿ⁻¹⁾, where n is any integer. If the frequency of the clock signal 108 applied to the input of the frequency divider 110 is greater than the frequency F, the frequency divider 110 may malfunction.

Adding the speed booster shell 102 to the frequency divider 110 may result in the frequency of the clock signal 108 applied to the frequency divider 110 input being equal to or lower than the frequency F. The lower clock frequency at the frequency divider 110 input may ensure that the frequency divider 110 does not malfunction. Moreover, the lower clock frequency of the clock signal 108 at the frequency divider 110 input may increase the operating frequency of the resulting frequency divider circuit 100 over the performance of the frequency divider 110 alone. For example, in embodiments in which the frequency divider 110 may be a six bit 270 MHz 1-to-63 core divider, the resulting circuit 100 may be a 504 MHz 2-to-129 divider. The control signal 106 may add the extra bit, i.e., the div<0> vector, to the binary code used to control the integer by which the frequency divider circuit 100 divides. The extra bit may be added as the least significant bit (LSB) in the binary code.

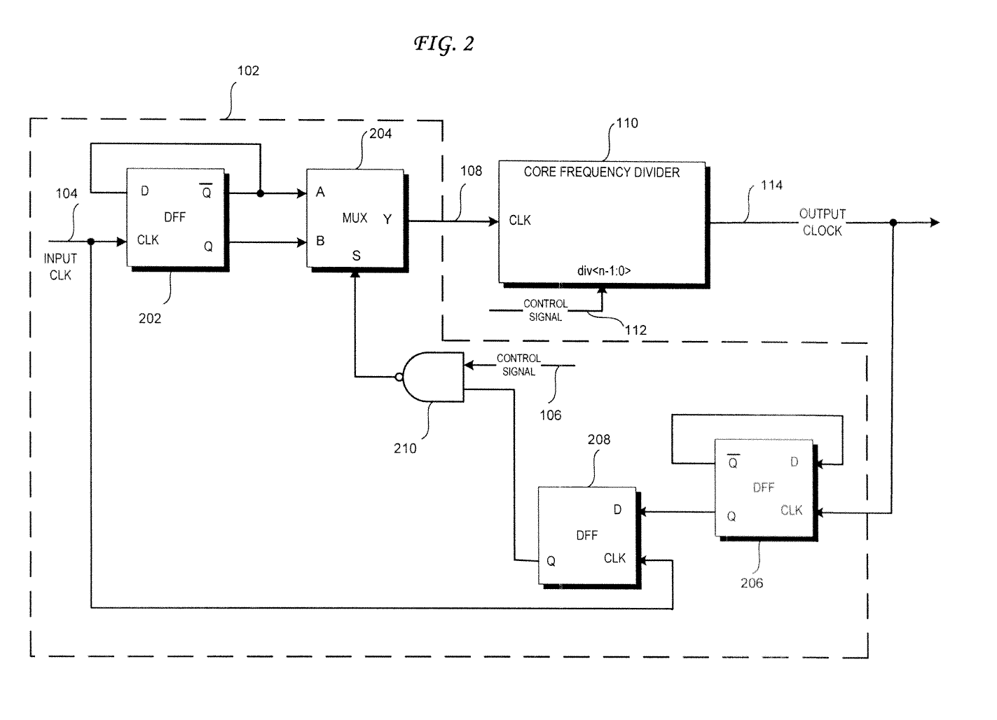

FIG. 2 is a block diagram of a frequency divider showing a speed booster in more detail according to an embodiment of the present invention. In the embodiment illustrated in FIG. 2, the speed booster shell 102 includes a D flip-flop 202 having its clock input coupled to the input clock 104. A second output of the D flip-flop 202 is fed back to the D input of the flip-flop 202.

Two outputs of the D flip-flop 202 are coupled to two inputs of a multiplexer 204. An output of the multiplexer 204 is coupled to an input of the frequency divider 110 as the clock signal 108. An output of the frequency divider 110 is coupled to the clock input of a second D flip-flop 206. A first output of the D flip-flop 206 is fed back to the D input of the flip-flop 206.

A second output of the D flip-flop 206 is coupled to the D input of a third flip-flop 208. The input clock 104 is coupled to the clock input of the third flip-flop 208. An output of the third flip-flop 208 is coupled to one input of a NAND gate 210. A second input of the NAND gate 210 is coupled to the control signal 106. An output of the NAND gate 210 is coupled to the select input of the multiplexer 204.

The D flip-flop 202 may generate the plurality of clock edges based on the input clock 104 and the output of the D flip-flop 202 that is fed back to the D input of the D flip-flop 202. On the rising edge of the input clock 104, the Q output of the D flip-flop 202 takes on the state of the D input of the D flip-flop 202 and delays it by one clock count. For some embodiments, the first D flip-flop 202 may divide the input frequency of the input clock 104 by two. This dividing by two may generate two clock edges with one-half (½F) delay between them.

One clock edge may be applied to the A input of the multiplexer 204 and another clock edge may be applied to the B input of the multiplexer 204. The multiplexer 204 may select at least one of the clock edges in response to a selection signal on the S input of the multiplexer 204. The output from the NAND gate 210 may provide the selection signal for the multiplexer 204.

For some embodiments, the multiplexer 204 may be an N-to-1 multiplexer, wherein N is an integer. When the multiplexer 204 is a two-to-one multiplexer, either the clock edge applied to the A input of the multiplexer 204 or the clock edge applied to the B input of the multiplexer 204 is output to clock the frequency divider 110 as the signal 108.

The frequency divider 110 divides the frequency F of the clock signal 108 by the value of the control signal 112 and generates an output clock 114. For some embodiments, the frequency divider 110 may be a Verilog one-to-eight divider. For other embodiments, the frequency divider 110 may be a Verilog one-to-ten divider. For still other embodiments, the frequency divider 110 may be any suitable divider capable of dividing the frequency F of the clock signal 108 by one up to 2⁽ⁿ⁻¹⁾, where n is any integer.

The output of the frequency divider 110 is applied to the clock input of the D flip-flop 206. One output of the D flip-flop 206 is fed back to the D input of the D flip-flop 206. A second output of the D flip-flop 206 may indicate the status of the output of the frequency divider 110. For some embodiments, the D flip-flop 206 may divide the frequency of the output clock 114 by two.

An output of the D flip-flop 206 is applied to the D input of the D flip-flop 208. The input clock 104 is applied to the clock input of the D flip-flop 208. On the rising edge of the input clock 104, the Q output of the D flip-flop 208 takes on the state of the D input of the D flip-flop 208, which is the Q output of the D flip-flop 206, and delays it by one clock count. The D flip-flop 208 thereby may synchronize the output from the D flip-flop 206 with the input clock 104.

An output of the D flip-flop 208 is applied to one input of the NAND gate 210. The control signal 106 is applied to a second input of the NAND gate 210. The control signal 106 concatenated with the control signal 112 may define the ratio of the frequency of the input clock 104 to the frequency of the output clock 114. The vector div<n:0> may be an n+1 binary code. The control signal 106 may be constantly applied and the value may be changed to be in accordance with a specific application.

If any state of the output of the D flip-flop 208 and the state of the control signal 106 are a first logic value, then the output of the NAND gate 210 will be a second logic value. Conversely, if both states of the output of the D flip-flop 208 and the state of control signal 106 are the second logic value, then the output of the NAND gate 210 will be the first logic value.

The output of the NAND gate 210 is applied to the multiplexer 204 to select either the clock on input A or the clock on input B. If the output of the NAND gate 210 is logic one, then the clock on input B is selected. If the output of the NAND gate 210 is logic zero, then the clock on input A is selected. The output of the D flip-flop 208 and the control signal 104 may indicate whether the clock edge selected by the multiplexer 204 and applied to the input of the frequency divider 110 is being counted on even times or odd times.

The output of the D flip-flop 208 may be either a logic zero or a logic one. The last bit of the control signal 106 may be either a logic zero or a logic one. Thus, there are a total of four conditions for the multiplexer 220 selection signal. Table 1 below indicates how the selection of the A input or the B input of the multiplexer 220 may be accomplished according to an embodiment of the present invention.

TABLE 1

| DFF 208 Q Output | Control Signal 106 | MUX 220 Y Output |
|---|---|---|
| 0 | 0 | B |
| 0 | 1 | B |
| 1 | 0 | B |
| 1 | 1 | A |

Keeping with the example described above in that the control signal 106 may be a div<0> vector and the control signal 112 may be a div<n:1> vector, after adding the speed booster shell 102 to the frequency divider 110, the frequency divider circuit 100 may divide the input clock 104 having a frequency F by even numbers among 1 up to 2⁽ⁿ⁺¹⁾ if the last digit of the control signal 104 has a value of zero. Alternatively, if the input clock 104 has a frequency 2F, the frequency divider circuit 100 may divide by odd numbers among 1 up to 2⁽ⁿ⁺¹⁾ if the last digit of the control signal 104 has a value of one. In this way, the speed booster shell 102 may double the capacity of the core frequency divider 110.

For some embodiments, the speed of the divide-by-two circuit 202 [may be much faster than a larger number divider. In a specific example, the core frequency divider 110 may be a 270 MHz 1-to-63 core divider. In this embodiment, the frequency divider circuit 100 may function as a 540 MHz 2-to-129 frequency divider.

In other embodiments of the invention, the input clock 104 may be used to generate multiple clock edges, and one of the multiple clock edges from input clock 104 may be used as clock input to the core divider 110. The resulting frequency divider speed booster may be M times faster than the core divider 110, with M greater than 2.

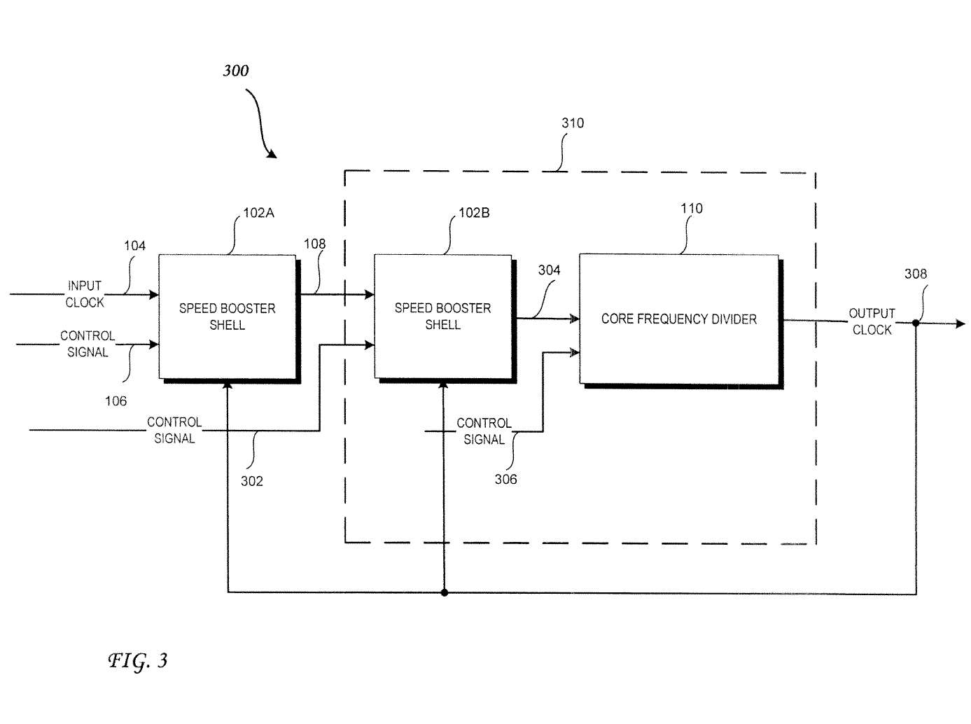

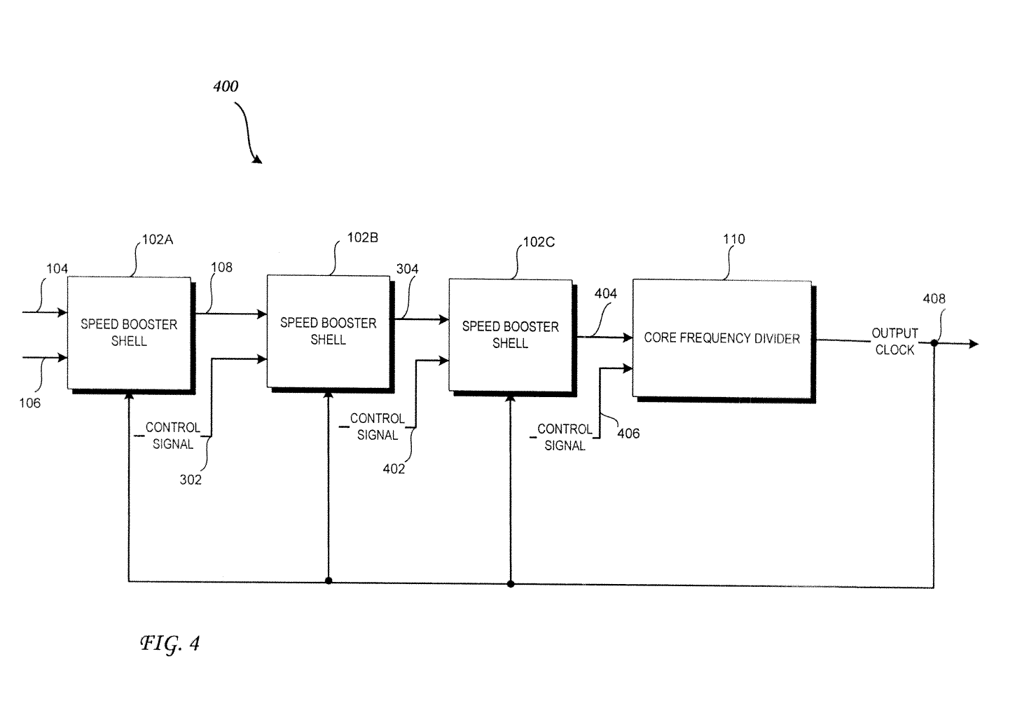

Although the frequency divider circuits 100 and 200 are illustrated as having one speed booster shell 102, in alternative embodiments the frequency divider circuits implemented according to embodiments of the present invention may include additional speed booster shells, as illustrated in FIG. 3 and FIG. 4. FIG. 3 illustrates a frequency divider circuit 300 according to one embodiment of the present invention. In the illustrated embodiment, a speed booster shell 102A includes a first input coupled to receive the input clock 104 and a second input coupled to receive the control signal 106.

The speed booster shell 102A generates the output signal 108, which is coupled to an input of a second speed booster shell 102B. The speed booster shell 102B also is coupled to receive a second control signal 302. The speed booster shell 102B generates an output signal 304.

The output signal 304 of the speed booster shell 102B is coupled to an input of the frequency divider 110. The frequency divider 110 has a second input coupled to receive a control signal 306. The frequency divider 110 generates an output clock 308, which is fed back to a third input of the speed booster shell 102A and a third input of the speed booster shell 102B. The combination of the speed booster shell 102B and the frequency divider 110 may provide a new core divider 310.

For some embodiments, the control signal 106 may be a div<0> vector, the control signal 302 may be a div<1> vector, and the control signal 306 may be a div<n:2> vector. In the illustrated embodiment, the first speed booster shell 102A adds one LSB to the binary code and the second speed booster shell 102B adds another LSB to the binary code. The result is two extra bits added to the binary code used to determine the amount by which the frequency divider 300 can divide an input clock 104.

As shown in FIG. 3, the speed booster shell 102 is used recursively as speed booster shells 102A and 102B to obtain the frequency divider circuit 300. The frequency divider circuit 300 may be four times faster than the original core frequency divider 110, and may divide input clock 104 frequencies up to four times greater than the core frequency divider 110 without the speed booster shells 102A and 102B.

FIG. 4 illustrates a frequency divider circuit 400 according to an alternative embodiment of the present invention in which the frequency divider 110 is boosted three times using substantially identical speed booster shells. In the illustrated embodiment, a speed booster shell 102A includes a first input coupled to receive the input clock 104 and a second input coupled to receive the control signal 106. The speed booster shell 102A generates the output signal 108.

The output signal 108 is coupled to an input of a second speed booster shell 102B. The speed booster shell 102B also is coupled to receive the control signal 302. The speed booster shell 102B generates the output signal 304.

The output signal 304 is coupled to an input of a third speed booster shell 102C. The speed booster shell 102C also is coupled to receive a control signal 402. The speed booster shell 102C generates an output signal 404.

The output signal 404 of the speed booster shell 102B is coupled to an input of the frequency divider 110. The frequency divider 110 has a second input coupled to receive a control signal 406. The frequency divider 110 generates an output clock 408, which is fed back to a third input of the speed booster shell 102A, a third input of the speed booster shell 102B, and a third input of the speed booster shell 102C.

For at least one embodiment, the frequency divider 110 may be a six bit 270 MHz 1-to-63 core divider, the control signal 106 may be a div<0> vector, the control signal 302 may be a div<1> vector, the control signal 402 may be a div<2> vector, and the control signal 106 may be a div<8:3> vector. In the illustrated embodiment, the first speed booster shell 102A adds one LSB to the binary code, the second speed booster shell 102B adds another LSB to the binary code, and the third speed booster shell 102C adds another LSB to the binary code. The result is three extra bits added to the binary code used to determine the amount by which the frequency divider circuit 400 can divide an input clock 104. The div<8:3> indicates that the frequency divider circuit 400 may be eight times faster than the core frequency divider 110 with three speed booster shells in the total circuit.

In this embodiment, the combination of the speed booster shell 102C and the frequency divider 110 may provide a seven-bit 540 MHz divider. The combination of the speed booster shells 102B and 102C and the frequency divider 110 may provide an eight-bit 1080 MHz divider.

The divider 400 results from the combination of the speed booster shells 102A, 102B, and 102C and the frequency divider 110, which may be a nine-bit 2160 MHz divider. The nine-bit 2160 MHz divider may be eight times faster than the frequency divider 110 alone. For some embodiments, if the input clock 104 is 2160 MHz, the nine-bit 2160 MHz divider 400 may divide a 2160 MHz input clock from 16 to 519. For some embodiments, each time a speed booster shell 102 is added, additional delay is introduced into the feedback loop. The additional delay may limit the lowest number that may be divided. The additional delay may shift the highest number that may be divided to a larger value. In the example described, sixteen is the lowest limit and 519 is the highest limit, and may be based on design simulation. If there were no delay in the loop (ideal case), the division performed may be from one to 512. The resulting frequency dividers 100, 200, 300, and/or 400 may be applied in a wide range of applications, e.g. imaging systems, personal computers, networks, and wireless systems.

From the foregoing, it will be appreciated that specific embodiments of the invention have been described herein for purposes of illustration, but that various modifications may be made without deviating from the invention. Certain aspects of the invention described in the context of particular embodiments may be combined or eliminated in other embodiments. Further, while advantages associated with certain embodiments may also exhibit such advantages, and not all embodiments need necessarily exhibit such advantages to fall within the scope of the invention. Accordingly, the invention is not limited except as by the appended claims.

What is claimed is:

1. An apparatus, comprising:
a logic circuit having a first input coupled to receive an input clock and a second input coupled to receive a control signal, the logic circuit coupled to generate a positive clock edge and a negative clock edge; and
a frequency divider having an input coupled to receive the positive clock edge and the negative clock edge, wherein the control signal is to determine whether the frequency divider is to receive the positive clock edge or the negative clock edge.

2. The apparatus of claim 1, wherein the logic circuit further comprises:
a first flip-flop to generate the positive and negative clock edges;
a multiplexer coupled to the first flip-flop to receive the positive and negative clock edges; and
a NAND gate having an output coupled to the multiplexer to select the positive or negative clock edge from the positive and negative clock edges.

3. The apparatus of claim 2, wherein the multiplexer comprises an N-to-1 multiplexer, wherein N is an integer.

4. The apparatus of claim 2, wherein the NAND gate output is to determine whether the frequency divider is to divide by an even integer or an odd integer.

5. The apparatus of claim 2, wherein the logic circuit further comprises a second flip-flop having an input coupled to receive an output of the frequency divider.

6. The apparatus of claim 5, wherein the logic circuit further comprises a third flip-flop having a first input coupled to receive the input clock and a second input coupled to receive an output of the second flip-flop, the third flip-flop to synchronize the output of the frequency divider with the input clock.

7. The apparatus of claim 6, wherein the NAND gate comprises a first input coupled to receive an output signal from the third flip-flop and a second input coupled to receive the control signal.

8. The apparatus of claim 7, wherein the first, second, and third flip-flops are D-type flip-flops.

9. An apparatus, comprising:
logic circuitry coupled to receive an input clock and a control signal, the logic circuitry coupled to generate a positive clock edge and a negative clock edge;
feedback circuitry coupled to the logic circuitry to determine whether the positive clock edge or the negative clock edge is to be coupled to a frequency divider, wherein the positive clock edge or the negative clock edge is to determine whether the frequency divider is to divide by an even integer or to divide by an odd integer.

10. The apparatus of claim 9, wherein the logic circuitry comprises a D-type flip-flop.

11. The apparatus of claim 9, wherein the feedback circuitry comprises:
a multiplexer coupled to the logic circuitry to receive the positive and negative clock edges; and
a NAND gate having an output coupled to the multiplexer to select the positive clock edge or the negative clock edge to be coupled to the frequency divider.

12. The apparatus of claim 11, wherein the multiplexer comprises an N-to-1 multiplexer, wherein N is an integer.

13. The apparatus of claim 11, wherein the multiplexer comprises a 2-to-1 multiplexer.

14. The apparatus of claim 11, wherein the feedback circuitry further comprises:
a first D-type flip-flop having an input coupled to receive an output of the frequency divider; and
a second D-type flip-flop having a first input coupled to receive the input clock and a second input coupled to receive an output of the second flip-flop, wherein the NAND gate further comprises a first input coupled to receive an output signal from the second D-type flip-flop and a second input coupled to receive the control signal.

15. A method, comprising:
generating a positive clock edge and a negative clock edge from an input clock;
switching between the positive clock edge and the negative clock edge;
applying the switched clock edges to a frequency divider input; and
dividing by an even integer or an odd integer based on whether the switched clock edge is positive or negative.

16. The method of claim 15, wherein the input clock is at least twice an operating frequency of the frequency divider.

17. The method of claim 16, further comprising synchronizing an output of the frequency divider with the input clock.

18. An apparatus, comprising:
first logic circuitry coupled to receive an input clock, the first circuitry coupled to switch between a first positive clock edge and a first negative clock edge;
second logic circuitry coupled to receive the first positive clock edge and the first negative clock edge, the second logic circuitry coupled to switch between a second positive clock edge and a second negative clock edge;
third logic circuitry coupled to receive the second positive clock edge and the second negative clock edge, the third logic circuitry coupled to switch between a third positive clock edge and a third negative clock edge; and
a frequency divider coupled to receive the third positive clock edge and the third negative clock edge, wherein a control signal input to the third logic circuitry is to determine whether the frequency divider is to receive the third positive clock edge or the third negative clock edge.

19. The apparatus of claim 18, wherein the third positive clock edge and the third negative clock edge are to determine whether the frequency divider is to divide by an even integer or an odd integer.

20. The apparatus of claim 19, wherein the first logic circuitry is coupled to receive an input clock having a first frequency and an operating frequency of the frequency divider.

21. The apparatus of claim 19, wherein selection of the at least one clock edge selected from among the third plurality of clock edges is determined based on the output of the frequency divider and the third control signal.
